(19) United States
(12) Patent Application Publication
(10) Pub. No.: US 2025/0240936 A1
(43) Pub. Date: Jul. 24, 2025

(54) ELECTRONIC-COMPONENT BATCH TRANSFER METHOD AND SYSTEM

(71) Applicant: Innostar service Inc., Taichung City (TW)

(72) Inventor: Chih-Meng WU, Taichung City (TW)

(21) Appl. No.: 18/984,134

(22) Filed: Dec. 17, 2024

(30) Foreign Application Priority Data
Jan. 23, 2024 (TW) 113102624

(51) Int. Cl. H05K 13/08; H05K 13/02; H05K 13/04

(52) U.S. Cl. CPC H05K 13/086; H05K 13/028; H05K 13/043; H05K 13/0465; H05K 13/0813

(57) ABSTRACT

An electronic-component batch transfer method including: driving an annular docking device to rotate step-wise to periodically provide a transfer period, the annular docking device having plural docking zones; performing an array loading operation, including driving a supply head to move down to the annular docking device to feed a plurality of electronic components into an array of reception holes of one of the docking zones that faces upward during the transfer period; and performing an implantation operation, including driving the annular docking device to release the electronic components in the reception holes of another one of the docking zones that faces downward to a plurality of solder pads of a corresponding circuit board.

### BACKGROUND OF THE INVENTION

### Field of the Invention

The invention relates to a method for transferring electronic components, especially to a method and system for transferring batches of electronic components.

### Description of the Related Art

As the functionality of electronic products continues to increase, many circuit board component bonding processes have involved transferring a large quantity of electronic components to a circuit board.

In a general electronic component transfer method, solder pads of the circuit board, formed by placing solder balls or solder bumps on contact pads of the circuit board, are the transfer targets during the transfer process, so that after electronic components are placed on and soldered to the solder pads, the electronic components can be fixedly bonded to the circuit board.

However, as conventional electronic component transfer operations generally adopt pick-and-place method, which has limited transfer efficiencies, their performances have gradually become insufficient for the demand of high volume electronic component transfer involved in advanced semiconductor packaging processes.

To solve the above mentioned problem, a novel batch transfer scheme is needed to quickly and accurately transfer a large quantity of electronic components onto a circuit board.

### SUMMARY OF THE INVENTION

One objective of the invention is to provide an electronic-component batch transfer method, which, by driving an annular docking device to rotate step-wise vertically, can allow an electronic-component array loading operation and an electronic-component batch implantation operation to be performed simultaneously, so as to efficiently bond a batch of electronic components to solder pads on a corresponding circuit board periodically.

Another objective of the invention is to provide an electronic-component batch transfer method, which can expedite the electronic-component array loading operation by utilizing a pneumatic operation.

Another objective of the invention is to provide an electronic-component batch transfer method, which can expedite the electronic-component array loading operation by utilizing a vibratory operation.

Another object of the invention is to provide an electronic-component batch transfer method, which, by utilizing a camera device and a pneumatic mechanism, can automatically ensure the completion of the electronic-component array loading operation and sweep back excess electronic components to at least one cavity that contains the electronic components.

Still another objective of the invention is to provide an electronic-component batch transfer system, which can significantly improve the efficiency and accuracy of the electronic-component batch transfer by adopting the aforementioned method.

To attain the above objectives, an electronic-component batch transfer method is proposed, the method being implemented by a control circuit and including:
driving an annular docking device to rotate step-wise to periodically provide a transfer period, where the annular docking device has a plurality of docking zones around a periphery thereof, each of the docking zones having an array of reception holes, and the docking zone facing upward serves as a component input zone and the docking zone facing downward serves as a component output zone during the transfer period;
performing an array loading operation, including driving a supply head to move down to the component input zone to feed a plurality of electronic components into the array of reception holes respectively during the transfer period; and
performing an implantation operation, including driving the annular docking device to release the electronic components in the reception holes of the component output zone downward to a plurality of solder pads of a corresponding circuit board respectively;
where the supply head has at least one inlet, at least one cavity, an outlet, and an up/down movable cover, the at least one inlet being used to receive a plurality of the electronic components, the at least one cavity being used to contain the electronic components, and the outlet being used to provide a downward exit of the electronic components after the cover is moved upward to make the outlet connected with the at least one cavity; each of the at least one cavity having an air slot for providing an air flow to blow the electronic components in the cavity toward the outlet during the array loading operation; and two sides of the annular docking device are each provided with an air knife device to sweep excess ones of the electronic components on the component input zone back into the at least one cavity.

In one embodiment, the reception holes in each of the docking zones have a distribution pattern, and the solder pads of the corresponding circuit board also have the distribution pattern.

In one embodiment, during the array loading operation, each of the docking zones is coupled to a vibration device to use a vibration to expedite the process of feeding the electronic components into the reception holes.

In one embodiment, each of the reception holes in each of the docking zones has an opening for receiving a negative air pressure to keep the electronic components from falling out of the reception holes during the rotation of the annular docking device.

In one embodiment, the cover has a camera device underneath to take an image of the component input zone, and the array loading operation includes: performing an image recognition procedure on the image to determine a distribution state of the electronic components on the component input zone; and performing a back-end operation according to the distribution state, the back-end operation including: if at least one of the reception holes is empty, introducing the air flow through the air slot of the at least one cavity to blow at least one electronic component in the at least one cavity toward the outlet; and if each of the reception holes holds one electronic component and at least one excess electronic component is present on a surface of the component input zone, driving at least one of the air knife devices to provide at least one air curtain to blow the at least one excess electronic component back into at least one of the at least one cavity.

In one embodiment, the electronic-component batch transfer method further includes a solder removal process, which includes using a cleansing device located on one side of the annular docking device to remove residual solder left on one of the docking zones that faces the cleansing device.

In one embodiment, the outlet of the supply head has an annular arcuate concave surface at a bottom side thereof, and each of the docking zones of the annular docking device has an annular arcuate convex surface to engage with the annular arcuate concave surface.

To attain the above objectives, the invention further proposes an electronic-component batch transfer system having a control circuit electrically coupled to a supply head electrically, an annular dock device, and a pair of air knife devices to implement a batch transfer method, the batch transfer method including:
driving the annular docking device to rotate step-wise to periodically provide a transfer period, where the annular docking device has a plurality of docking zones around a periphery thereof, each of the docking zones having an array of reception holes, and the docking zone facing upward serves as a component input zone and the docking zone facing downward serves as a component output zone during the transfer period;
performing an array loading operation, including driving the supply head to move down to the component input zone to feed a plurality of electronic components into the array of reception holes respectively during the transfer period; and
performing an implantation operation, including driving the annular docking device to release the electronic components in the reception holes of the component output zone downward to a plurality of solder pads of a corresponding circuit board respectively;
where the supply head has at least one inlet, at least one cavity, an outlet, and an up/down movable cover, the at least one inlet being used to receive a plurality of the electronic components, the at least one cavity being used to contain the electronic components, and the outlet being used to provide a downward exit of the electronic components after the cover is moved upward to make the outlet connected with the at least one cavity; each of the at least one cavity having an air slot for providing a compressed air flow to blow the electronic components in the cavity toward the outlet during the array loading operation; and two sides of the annular docking device are each provided with an air knife device to sweep excess ones of the electronic components on the component input zone back into the at least one cavity.

In one embodiment, the reception holes in each of the docking zones have a distribution pattern, and the solder pads of the corresponding circuit board also have the distribution pattern.

In one embodiment, the electronic-component batch transfer system further includes a vibration device, where, during the array loading operation, each of the docking zones is coupled to the vibration device to use a vibration to expedite the process of feeding the electronic components into the reception holes.

In one embodiment, each of the reception holes in each of the docking zones has an opening for receiving a negative air pressure to keep the electronic components from falling out of the reception holes during the rotation of the annular docking device.

In one embodiment, the electronic-component batch transfer system further includes a camera device, where the camera device is disposed underneath the cover to take an image of the component input zone, and the array loading operation includes: performing an image recognition procedure on the image to determine a distribution state of the electronic components on the component input zone; and performing a back-end operation according to the distribution state, the back-end operation including: if at least one of the reception holes is empty, introducing the compressed air flow through the air slot of the at least one cavity to blow at least one electronic component in the at least one cavity toward the outlet; and if each of the reception holes holds one electronic component and at least one excess electronic component is present on a surface of the component input zone, driving at least one of the air knife devices to provide at least one air curtain to blow the at least one excess electronic component back into at least one of the at least one cavity.

In one embodiment, the electronic-component batch transfer system further includes a cleansing device located on one side of the annular docking device, and the batch transfer method further includes a solder removal process, which includes using the cleansing device to remove residual solder left on one of the docking zones that faces the cleansing device.

In one embodiment, the outlet of the supply head has an annular arcuate concave surface at a bottom side thereof, and each of the docking zones of the annular docking device has an annular arcuate convex surface to engage with the annular arcuate concave surface.

To make it easier for our examiner to understand the objective of the invention, its structure, innovative features, and performance, we use preferred embodiments together with the accompanying drawings for the detailed description of the invention.

### BRIEF DESCRIPTION OF THE DRAWINGS

FIG. 1 illustrates a block diagram of the electronic-component batch transfer system according to one embodiment of the invention;

FIG. 2 is a schematic diagram of one embodiment of a supply head of the electronic-component batch transfer system of FIG. 1;

FIG. 3 is a schematic diagram of one embodiment of an annular docking device of the electronic-component batch transfer system of FIG. 1;

FIG. 4 is a schematic diagram of one embodiment of a docking zone of the annular docking device of FIG. 3;

FIG. 5 is a schematic diagram of another embodiment of the supply head and the annular docking device of the electronic-component batch transfer system of FIG. 1; and

FIG. 6 illustrates a flow chart of the electronic-component batch transfer method according to one embodiment of the invention.

### DETAILED DESCRIPTION OF THE PREFERRED EMBODIMENTS

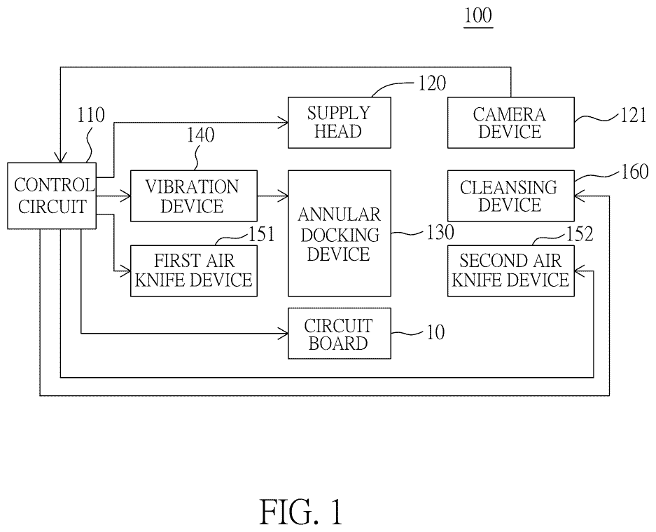

Please refer to FIG. 1, which illustrates a block diagram of the electronic-component batch transfer system according to one embodiment of the invention. As shown in FIG. 1, an electronic-component batch transfer system 100 is used to perform a batch transfer procedure to transfer electronic components onto a circuit board 10, and the electronic-component batch transfer system 100 has a control circuit 110 coupled to a supply head 120, a camera device 121, an annular docking device 130, a vibration device 140, a first air knife device 151, a second air knife device 152, and a cleansing device 160 to perform the batch transfer process by executing a program, where the electronic components can be copper pins or passive components.

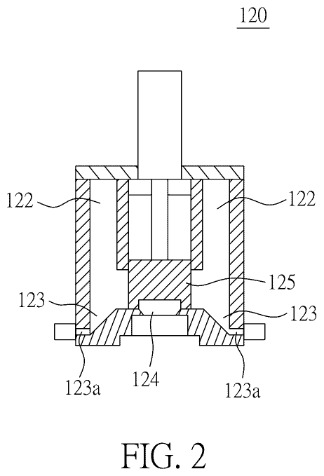

Please refer to FIG. 2, which is a schematic diagram of one embodiment of the supply head 120 of the electronic-component batch transfer system 100 of FIG. 1. As shown in FIG. 2, the supply head 120 has at least one inlet 122, at least one cavity 123, an outlet 124, and a cover 125 that is up/down movable. The at least one inlet 122 is used to receive a plurality of the electronic

components, the at least one cavity 123 is used to contain a quantity of the electronic components, and the outlet 124 is used to provide a downward exit for the electronic components contained in the at least one cavity 123 after the cover 125 is moved upward to make the outlet 124 connected with the at least one cavity 123; each of the at least one cavity 123 has an air slot 123a for providing a compressed air flow to blow the electronic components contained therein toward the outlet 124.

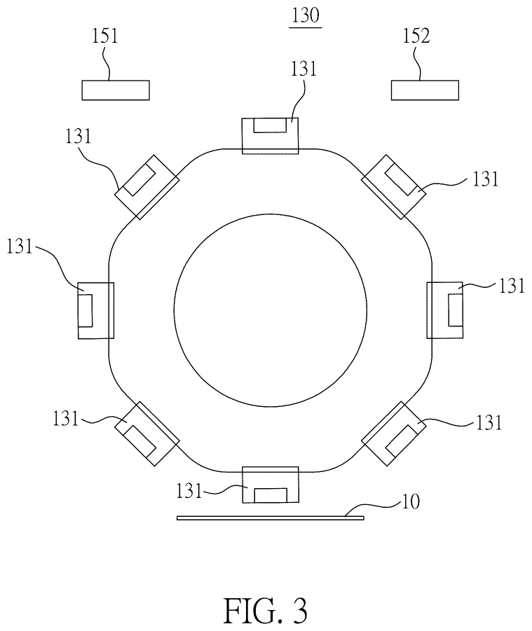

Please refer to FIG. 3, which is a schematic diagram of one embodiment of the annular docking device 130 of the electronic-component batch transfer system 100 of FIG. 1. As shown in FIG. 3, the annular docking device 130, having a plurality of docking zones 131 around a periphery thereof, rotates step-wise to periodically provide a transfer period, where each of the docking zones 131 has an array of reception holes, and during the transfer period, the docking zone 131 facing upward serves as a component input zone and the docking zone 131 facing downward serves as a component output zone. In addition, a pair of air knife devices (a first air knife device 151, a second air knife device 152) are disposed on two sides of the annular docking device 130 for blowing excess aforementioned electronic components on the component input zone back into the at least one cavity 123.

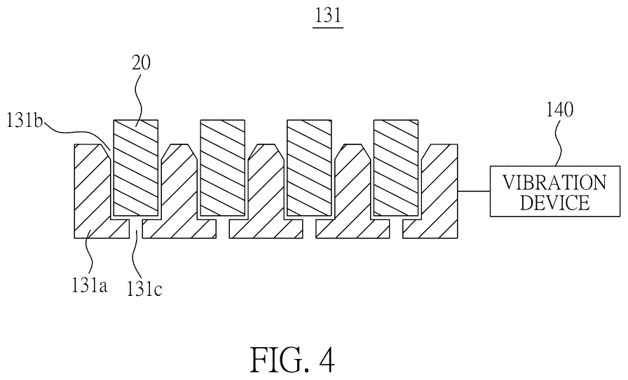

In addition, please refer to FIG. 4, which is a schematic diagram of one embodiment of a docking zone 131 of the annular docking device 130 of FIG. 3. As shown in FIG. 4, the docking zone 131 includes an assembly plate 131a having an array of reception holes 131b. In addition, the vibration device 140 is coupled to the assembly plate 131a to expedite the process of feeding electronic components 20 into the reception holes 131b; and each reception hole 131b has an opening 131c for receiving a negative air pressure to keep the electronic component 20 from falling out of the reception hole 131b.

To be specific, the batch transfer procedure includes:
(A) the control circuit 110 drives the annular docking device 130 to rotate step-wise to periodically provide a transfer period, where during the transfer period, the docking zone 131 facing upward serves as a component input zone and the docking zone 131 facing downward serves as a component output zone;
(B) the control circuit 110 performs an array loading operation, including driving the supply head 120 to move down to the component input zone to feed a plurality of electronic components 20 into the array of reception holes 131b respectively during the transfer period; and
(C) the control circuit 110 performs an implantation operation, including driving the annular docking device 130 to release electronic components 20 in the reception holes of the component output zone downward to a plurality of solder pads of a corresponding circuit board 10 respectively.

During the array loading operation, the control circuit 110 may drive an air compressor (not shown in the figure) or one of the air knife devices to provide a compressed air flow to the air slot 123a of the cavities 123 to blow the electronic components 20 therein toward the outlet 124.

In addition, the camera device 121 can be disposed underneath the cover 125 to take an image of the component input zone during the array loading operation, and the control circuit 110 can perform an image recognition procedure on the image to determine a distribution state of the electronic components 20 on the component input zone, and perform a back-end operation according to the distribution state. To be specific, the back-end operation includes: if at least one reception hole 131b is empty, drives the air compressor or one of the air knife devices to generate a compressed air flow through the air slot 123a of the at least one cavity 123 to blow at least one electronic component 20 in the at least one cavity 123 toward the outlet 124; and if each of the reception holes 131b holds one electronic component 20 and at least one excess electronic component 20 is present on a surface of the component input zone, drives at least one of the air knife devices (151, 152) to provide at least one air curtain to blow the at least one excess electronic component 20 back into at least one cavity 123. To be specific, the air knife devices (151, 152) are connected to a pair of air nozzles (not shown in the figure) of the supply head 120 correspondingly via a pair of hoses, the pair of air nozzles being disposed on two locations of the housing of the supply head 120 that are higher than the outlet 124, so as to provide at least one air curtain traveling obliquely downward towards the outlet 124 to blow excess electronic components 20 back into at least one cavity 123.

In addition, during the array loading operation, the control circuit 110 can drive the vibration device 140 to vibrate the component input zone to expedite the process of feeding the electronic components 20 into the reception holes 131b.

In addition, after the array loading operation is completed, to ensure that the electronic components 20 held in the docking zone 131 will not fall out of the reception holes 131b during the rotation of the annular docking device 130, the control circuit 110 can drive the air compressor or one of the air knife devices to perform a negative air pressure operation on the opening 131c of the reception holes 131b to make the electronic components 20 held erectly in the reception holes 131b.

In addition, the reception holes 131b of each docking zone 131 have a distribution pattern, and the solder pads of a corresponding circuit board 10 also have the distribution pattern, so that the electronic components 20 can be accurately adhered to those solder pads of the corresponding circuit board 10.

In addition, the batch transfer procedure may further include a residual solder removal procedure, which includes using the control circuit 110 to drive the cleansing device 160 to remove residual solder left on one of the docking zones 131 that faces the cleansing device 160.

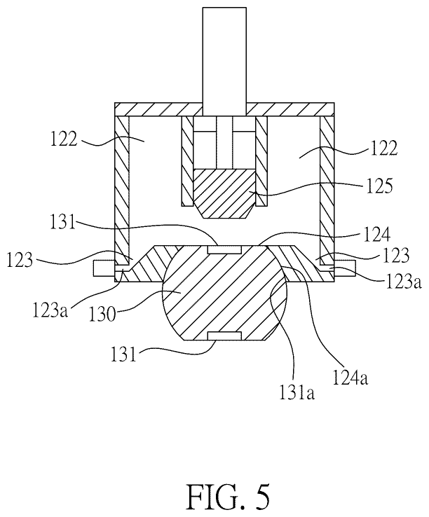

In addition, the outlet 124 of the supply head 120 has an annular arcuate concave surface at a bottom side thereof, and each of the docking zones 131 of the annular docking device 130 has an annular arcuate convex surface to engage with the annular arcuate concave surface, so that when the supply head 120 is moved down to the component input zone for performing the array loading operation, the annular arcuate concave surface and the annular arcuate convex surface can be air tightly joined together to optimize the performance of the compressed air flow, the negative air pressure operation, and the air curtain required in the array loading operation. Please refer to FIG. 5, which is a schematic diagram of another embodiment of the supply head 120 and the annular docking device 130 of the electronic-component batch transfer system 100 of FIG. 1. As shown in FIG. 5, the outlet 124 of the supply head 120 has an annular arcuate concave surface 124a at a bottom side thereof, and each of the docking zones 131 of the annular docking device 130 has an annular arcuate convex surface 131a to engage with the annular arcuate concave surface 124a to provide an air tight effect.

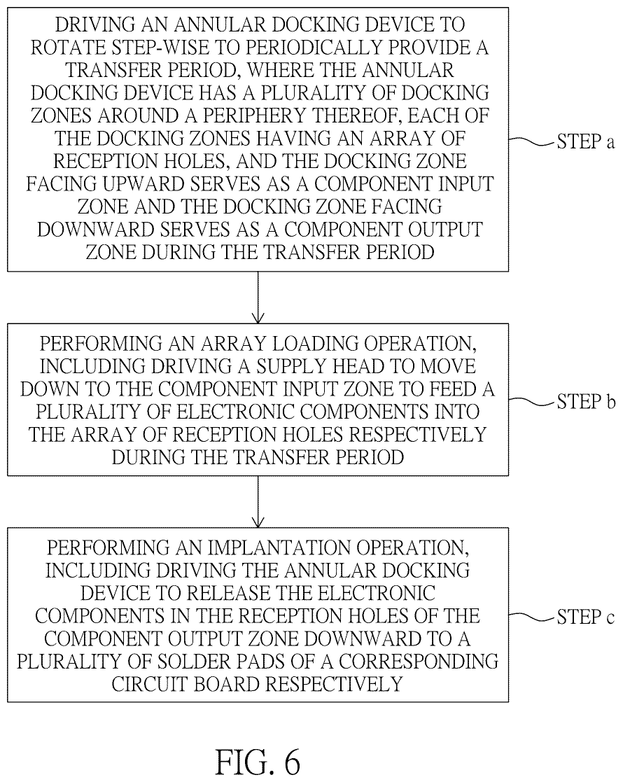

As can be seen from the above disclosure, the invention discloses an electronic-component batch transfer method. Please refer to FIG. 6, which illustrates a flow chart of the electronic-component batch transfer method according to one embodiment of the invention, the method being implemented by a control circuit executing a program and including the following steps: driving an annular docking device to rotate step-wise to periodically provide a transfer period, where the annular docking device has a plurality of docking zones around a periphery thereof, each of the docking zones having an array of reception holes, and the docking zone facing upward serves as a component input zone and the docking zone facing downward serves as a component output zone during the transfer period (step a); performing an array loading operation, including driving a supply head to move down to the component input zone to feed a plurality of electronic components into the array of reception holes respectively during the transfer period (step b); and performing an implantation operation, including driving the annular docking device to release the electronic components in the reception holes of the component output zone downward to a plurality of solder pads of a corresponding circuit board respectively (step c).

In the above steps, to be more specific, the supply head has at least one inlet, at least one cavity, an outlet, and an up/down movable cover, the at least one inlet being used to receive a plurality of the electronic components, the at least one cavity being used to contain the electronic components, and the outlet being used to provide a downward exit of the electronic components after the cover is moved upward to make the outlet connected with the at least one cavity; each of the at least one cavity having an air slot for providing an air flow to blow the electronic components in the cavity toward the outlet during the array loading operation; and both sides of the annular docking device are provided with an air knife device to sweep excess ones of the electronic components on the component input zone back into the at least one cavity.

In addition, during the array loading operation, each of the docking zones is coupled to a vibration device to use a vibration to expedite the process of feeding the electronic components into the reception holes.

In one embodiment, each of the reception holes in each of the docking zones has an opening for receiving a negative air pressure to keep the electronic components from falling out of the reception holes during the rotation of the annular docking device.

In one embodiment, the cover has a camera device underneath to take an image of the component input zone, and the array loading operation includes: performing an image recognition procedure on the image to determine a distribution state of the electronic components on the component input zone; and performing a back-end operation according to the distribution state, the back-end operation including: if at least one of the reception holes is empty, introducing the air flow through the air slot of the at least one cavity to blow at least one electronic component in the at least one cavity toward the outlet; and if each of the reception holes holds one electronic component and at least one excess electronic component is present on a surface of the component input zone, driving at least one of the air knife devices to provide at least one air curtain to blow the at least one excess electronic component back into at least one of the at least one cavity.

In addition, the reception holes in each of the docking zones have a distribution pattern, and the solder pads of the corresponding circuit board also have the distribution pattern.

In addition, the electronic-component batch transfer method further includes a solder removal process, which includes using a cleansing device located on one side of the annular docking device to remove residual solder left on one of the docking zones that faces the cleansing device.

With the above disclosure, the invention can offer the following advantages:
(A) the electronic-component batch transfer method of the invention, by driving an annular docking device to rotate step-wise vertically, can allow an electronic-component array loading operation and an electronic-component batch implantation operation to be performed simultaneously, so as to efficiently bond a batch of electronic components to solder pads on a corresponding circuit board periodically;
(B) the electronic-component batch transfer method of the invention can expedite the electronic-component array loading operation by utilizing a pneumatic operation;
(C) the electronic-component batch transfer method of the invention can expedite the electronic-component array loading operation by utilizing a vibratory operation;
(D) the electronic-component batch transfer method of the invention can utilize a camera device and a pneumatic mechanism to automatically ensure the completion of the electronic-component array loading operation and sweep back excess electronic components to at least one cavity that contains the electronic components; and
(E) the electronic-component batch transfer system of the invention can significantly improve the efficiency and accuracy of the electronic-component batch transfer by adopting the aforementioned method.

While the invention has been described by way of example and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

In summation of the above description, the present invention herein enhances the performance over the conventional structure and further complies with the patent application requirements and is submitted to the Patent and Trademark Office for review and granting of the commensurate patent rights.

What is claimed is:

1. An electronic-component batch transfer method, which is implemented by a control circuit and includes:
driving an annular docking device to rotate step-wise to periodically provide a transfer period, where the annular docking device has a plurality of docking zones around a periphery thereof, each of the docking zones having an array of reception holes, and the docking zone facing upward serves as a component input zone and the docking zone facing downward serves as a component output zone during the transfer period;
performing an array loading operation, including driving a supply head to move down to the component input zone to feed a plurality of electronic components into the array of reception holes respectively during the transfer period; and
performing an implantation operation, including driving the annular docking device to release the electronic components in the reception holes of the component output zone downward to a plurality of solder pads of a corresponding circuit board respectively;
wherein the supply head has at least one inlet, at least one cavity, an outlet, and an up/down movable cover, the at least one inlet being used to receive a plurality of the electronic components, the at least one cavity being used to contain the electronic components, and the outlet being used to provide a downward exit of the electronic components after the cover is moved upward to make the outlet connected with the at least one cavity; each of the at least one cavity having an air slot for providing an air flow to blow the electronic components in the cavity toward the outlet during the array loading operation; and two sides of the annular docking device are each provided with an air knife device to sweep excess ones of the electronic components on the component input zone back into the at least one cavity.

2. The electronic-component batch transfer method as disclosed in claim 1, wherein the reception holes in each of the docking zones have a distribution pattern, and the solder pads of the corresponding circuit board also have the distribution pattern.

3. The electronic-component batch transfer method as disclosed in claim 1, wherein, during the array loading operation, each of the docking zones is coupled to a vibration device to use a vibration to expedite a process of feeding the electronic components into the reception holes.

4. The electronic-component batch transfer method as disclosed in claim 1, wherein each of the reception holes in each of the docking zones has an opening for receiving a negative air pressure to keep the electronic components from falling out of the reception holes during a rotation of the annular docking device.

5. The electronic-component batch transfer method as disclosed in claim 1, wherein the cover has a camera device underneath to take an image of the component input zone, and the array loading operation includes: performing an image recognition procedure on the image to determine a distribution state of the electronic components on the component input zone; and performing a back-end operation according to the distribution state, the back-end operation including: if at least one of the reception holes is empty, introducing the air flow through the air slot of the at least one cavity to blow at least one electronic component in the at least one cavity toward the outlet; and if each of the reception holes holds one electronic component and at least one excess electronic component is present on a surface of the component input zone, driving at least one of the air knife devices to provide at least one air curtain to blow the at least one excess electronic component back into at least one of the at least one cavity.

6. The electronic-component batch transfer method as disclosed in claim 1, which further includes a solder removal process, which includes using a cleansing device located on one side of the annular docking device to remove residual solder left on one of the docking zones that faces the cleansing device.

7. The electronic-component batch transfer method as disclosed in claim 1, wherein the outlet of the supply head has an annular arcuate concave surface at a bottom side thereof, and each of the docking zones of the annular docking device has an annular arcuate convex surface to engage with the annular arcuate concave surface.

8. An electronic-component batch transfer system having a control circuit electrically coupled to a supply head electrically, an annular dock device, and a pair of air knife devices to implement a batch transfer method, the batch transfer method including:
driving the annular docking device to rotate step-wise to periodically provide a transfer period, where the annular docking device has a plurality of docking zones around a periphery thereof, each of the docking zones having an array of reception holes, and the docking zone facing upward serves as a component input zone and the docking zone facing downward serves as a component output zone during the transfer period;
performing an array loading operation, including driving the supply head to move down to the component input zone to feed a plurality of electronic components into the array of reception holes respectively during the transfer period; and
performing an implantation operation, including driving the annular docking device to release the electronic components in the reception holes of the component output zone downward to a plurality of solder pads of a corresponding circuit board respectively;
wherein the supply head has at least one inlet, at least one cavity, an outlet, and an up/down movable cover, the at least one inlet being used to receive a plurality of the electronic components, the at least one cavity being used to contain the electronic components, and the outlet being used to provide a downward exit of the electronic components after the cover is moved upward to make the outlet connected with the at least one cavity; each of the at least one cavity having an air slot for providing a compressed air flow to blow the electronic components in the cavity toward the outlet during the array loading operation; and two sides of the annular docking device are each provided with an air knife device to sweep excess ones of the electronic components on the component input zone back into the at least one cavity.

9. The electronic-component batch transfer system as disclosed in claim 8, wherein the reception holes in each of the docking zones have a distribution pattern, and the solder pads of the corresponding circuit board also have the distribution pattern.

10. The electronic-component batch transfer system as disclosed in claim 8, which further comprises a vibration device, and during the array loading operation, each of the docking zones is coupled to the vibration device to use a vibration to expedite a process of feeding the electronic components into the reception holes.

11. The electronic-component batch transfer system as disclosed in claim 8, wherein each of the reception holes in each of the docking zones has an opening for receiving a negative air pressure to keep the electronic components from falling out of the reception holes during a rotation of the annular docking device.

12. The electronic-component batch transfer system as disclosed in claim 8, which further comprises a camera device, the camera device being disposed underneath the cover to take an image of the component input zone, and the array loading operation including: performing an image recognition procedure on the image to determine a distribution state of the electronic components on the component input zone; and performing a back-end operation according to the distribution state, the back-end operation including: if at least one of the reception holes is empty, introducing the compressed air flow through the air slot of the at least one cavity to blow at least one electronic component in the at least one cavity toward the outlet; and if each of the reception holes holds one electronic component and at least one excess electronic component is present on a surface of the component input zone, driving at least one of the air knife devices to provide at least one air curtain to blow the at least one excess electronic component back into at least one of the at least one cavity.

13. The electronic-component batch transfer system as disclosed in claim 8, which further comprises a cleansing device located on one side of the annular docking device, and the batch transfer method further includes a solder removal process, which includes using the cleansing device to remove residual solder left on one of the docking zones that faces the cleansing device.

14. The electronic-component batch transfer system as disclosed in claim 8, wherein the outlet of the supply head has an annular arcuate concave surface at a bottom side thereof, and each of the docking zones of the annular docking device has an annular arcuate convex surface to engage with the annular arcuate concave surface.
